(19) United States
(12) Patent Application Publication
(10) Pub. No.: US 2007/0037075 A1
(43) Pub. Date: Feb. 15, 2007

(54) Inkjet printhead and method of fabricating color filter

(75) Inventors: Kye-si Kwon, Seoul (KR); Seung-joo Shin, Seoul (KR); Sung-woong Kim, Suwon-si (KR); Jung-yong Lee, Seongnam-si (KR); Sang-il Kim, Suwon-si (KR)

Correspondence Address: STANZIONE & KIM, LLP, 919 18TH STREET, N.W., SUITE 440, WASHINGTON, DC, 20006, US

(73) Assignee: SAMSUNG Electronics Co., Ltd., Suwon-si (KR)

(21) Appl. No.: 11/491,928

(22) Filed: Jul. 25, 2006

(30) Foreign Application Priority Data
Aug. 2, 2005 (KR) 2005-70648

(51) Int. Cl. G03F 1/00

(52) U.S. Cl. 430/7

(57) ABSTRACT

An inkjet printhead and a method of fabricating a color filter with a uniform thickness. In the method, a transparent substrate is prepared, and a black matrix of a pixel pattern is formed on the transparent substrate. At least one pixel on the transparent substrate is selected, and an ink is ejected into the selected pixel in order to fabricate the color filter. The ejected ink is then promptly dried using a dryer.

### CROSS-REFERENCE TO RELATED APPLICATIONS

This application claims the benefit of Korean Patent Application No. 10-2005-0070648, filed on Aug. 2, 2005, in the Korean Intellectual Property Office, the disclosure of which is incorporated herein in its entirety by reference.

### BACKGROUND OF THE INVENTION

1. Field of the Invention

The present general inventive concept relates to a method of fabricating a color filter for a display, and more particularly, to an inkjet printhead and method of fabricating a color filter with a uniform thickness.

2. Description of the Related Art

With the advance of portable devices (specifically, portable PCs), LCDs (specifically, color LCDs) are increasingly in demand. However, the recent wide use of the LCDs and the high demand for such displays requires a reduction in LCD manufacturing costs. Since color filters are particularly expensive to fabricate, color filter fabrication costs must be greatly reduced in order to minimize the LCD manufacturing costs.

A color filter fabrication method is very important for implementing the high image quality of LCDs. Many color filter fabrication methods have been proposed to implement the high image quality of LCDs. Some examples of conventional color filter fabrication methods are a pigment dispersion method, a dyeing method, an electrodeposition method, and a printing method.

In the pigment dispersion method, a pigment dispersion photosensitive resin layer is formed on a substrate and then patterned into a monochromic pattern. This process is then repeated three times, thereby obtaining R/G/B color filter layers.

In the dyeing method, a glass substrate is coated thereon with a water-soluble high-molecular dyeing material, the dyeing material is patterned into a predetermined pattern using photolithography, and a colored pattern is obtained by immersing the predetermined pattern into a dyeing solution. This process is then repeated three times, thereby obtaining R/G/B color filter layers.

In the electrodeposition method, a transparent electrode is patterned on a substrate, and the resulting structure is immersed into an electrodeposition coating solution to electrodeposit a first color. This process is repeated three times, thereby forming R/G/B color filter layers. Finally, the formed R/G/B color filter layers are sintered.

In the printing method, a pigment is dispersed into a thermosetting resin to perform a printing process three times, thereby forming R/G/B color filter layers. The thermosetting resin is then set to form a colored layer.

In all the above methods, a protection layer may be formed on the colored layers.

The common feature of the above methods is that R/G/B colored layers are obtained by repeating an identical process three times. This, however, increases the color filter fabrication cost and reduces the processing yield. In addition, the conventional electrodeposition method is limited in terms of a pattern shape and is thus difficult to apply to TFT LCDs. Moreover, since the conventional printing method is low in resolution and smoothness, a fine-pitch pattern is difficult to form using the printing method.

Color filter fabrication methods for solving the above problems by using an inkjet printing process are disclosed in Japanese Patent Laid-open Publication Nos. SHO 59-75205, SHO 63-235901 and HEI 1-217320. In these color fabrication methods, R/G/B colorant-containing ink is sprayed onto a transparent substrate by an inkjet printing process, and the sprayed ink is dried to form a colored image region. In color filter fabrication methods using such an inkjet printing process, R/G/B pixels can be simultaneously formed, thus simplifying the fabrication process, and reducing fabrication costs.

FIG. 1A is a schematic perspective view of a color filter fabricated by a conventional inkjet printing process. FIG. 1B is a cross-sectional view taken along line A-A′ of FIG. 1A to illustrate a cross-section of a pixel in an edge region of a substrate. FIG. 1C is a cross-sectional view taken along line B-B′ of FIG. 1A to illustrate a cross-section of a pixel in a center region of the substrate.

Referring to FIGS. 1A through 1C, a block matrix 4 corresponding to a pattern of pixels 3 is formed on a substrate 2, and each pixel 3 is filled with ink 6 for fabricating a color filter. A comparison of FIGS. 1B and 1C illustrates the difference in thickness between pixels located in an edge region and pixels located in a center region of the substrate 2. This non-uniform thickness of the color filter causes a color mottle between edge region pixels and center region pixels. The reason for this non-uniform thickness is that pigment aggregation occurs in the ink because the edge region and the center region are different from each other in the drying speed of the ink and in the vaporizing speed of a solvent contained in the ink. Accordingly, countermeasures are required in order to solve these problems.

### SUMMARY OF THE INVENTION

The present general inventive concept provides an inkjet printhead to form a color filter, and a method of fabricating a color filter, and a color filter.

Additional aspects and advantages of the present general inventive concept will be set forth in part in the description which follows and, in part, will be obvious from the description, or may be learned by practice of the general inventive concept.

The foregoing and/or other aspects of the present inventive concept may be achieved by providing an inkjet printhead to form a color filter including an ink ejection head including one or more ejection nozzles and ejecting ink into a pixel formed on a substrate to fabricate the color filter, and a dryer installed near the ink ejection head to promptly dry the ink ejected into the pixel.

The dryer may include a heating element and a support head to support the heating element, and the heating element may be a micro heater or an IR lamp. The heating element may be provided with a predetermined number of micro heaters or IR (infra red) lamps such that the predetermined number of micro heaters or IR lamps corresponds to a number of ejection nozzles. In this case, each of the micro heaters or IR lamps 31 may have the same or similar width as the pixel.

The dryer may be installed in a body and may be attached either with or separately from one side of the ink ejection head. When the dryer is installed with the ink ejection head, the dryer and the ink ejection head form a body 31a. The dryer may either be installed at a side opposite a moving direction of the ink ejection head, or may be installed spaced apart from one side of the ink ejection head by a predetermined distance.

The foregoing and/or other aspects of the present inventive concept may also be achieved by providing a method of fabricating a color filter, the method including, preparing a transparent substrate, forming a block matrix of a pixel pattern on the transparent substrate, selecting at least one pixel of the pixel pattern on the transparent substrate and ejecting ink into the selected pixel to fabricate the color filter, and promptly drying the ejected ink using a dryer.

The dryer may include a heating element and a support head to support the heating element. The heating element may be a micro heater or an infra red (IR) lamp.

The ejecting of the ink into the pixel may be performed simultaneously with the drying of the ejected ink. In addition, the ejecting of ink into the pixel and the drying of the ejected ink may be continuously repeated several times to fabricate the color filter.

The block matrix may be formed using photolithography.

The foregoing and/or other aspects of the present inventive concept may also be achieved by providing a method of fabricating a color filter, the method including ejecting ink into a pixel formed on a substrate using an ink ejection head including one or more ejection nozzles, and promptly drying the ink ejected into the pixel using a dryer installed near the ink ejection head.

The foregoing and/or other aspects of the present inventive concept may also be achieved by providing a method of fabricating a color filter, the method including forming a pixel pattern including pixels on a transparent substrate, depositing a predetermined material including a colorant in the pixels of the pixel pattern to fabricate the color filter, and promptly drying the deposited predetermined material using a dryer.

The pixels of the pixel pattern may include at least one edge region pixel and at least one center region pixel, and the thickness of the color filter can be uniform as between the at least one edge region pixel and the at least one center region pixel.

The predetermined material may be ink and may be deposited using an ink ejection head. The ink may include a solvent having a vaporizing speed which can be equalized by the prompt drying of the ink.

The predetermined material may be deposited simultaneously with the drying of the predetermined material and the pixels in the pixel pattern may have a uniform thickness.

The foregoing and/or other aspects of the present inventive concept may be achieved by providing a color filter including a substrate, a matrix on the substrate to form pixels in a pixel pattern, and ink deposited in the pixels having a uniform thickness.

The pixels in the pixel pattern may include at least one edge region pixel and at least one center region pixel, and color mottle between the at least one edge region pixel and the at least one center region pixel may be suppressed.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1A is a schematic perspective view illustrating a color filter fabricated by a conventional inkjet printing process;

FIG. 1B is a cross-sectional view that is taken along line A-A′ of FIG. 1A to illustrate a cross-section of a pixel in an edge region of a substrate;

FIG. 1C is a cross-sectional view that is taken along line B-B′ of FIG. 1A to illustrate a cross-section of a pixel in a center region of a substrate;

FIGS. 2A and 2B are, respectively, perspective and side views illustrating an inkjet printhead to fabricate a color filter, according to an embodiment of the present inventive concept; and

FIGS. 3A and 3D are perspective views illustrating a color filter fabrication method according to an embodiment of the present inventive concept.

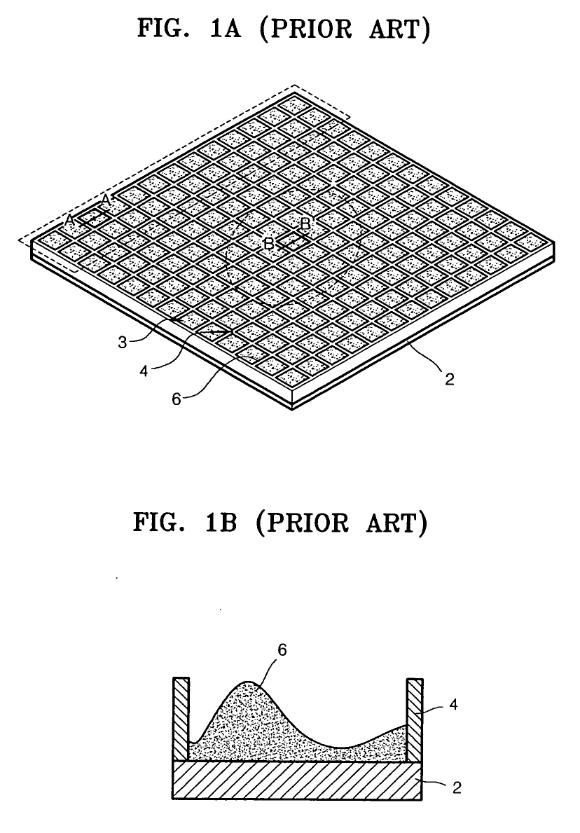

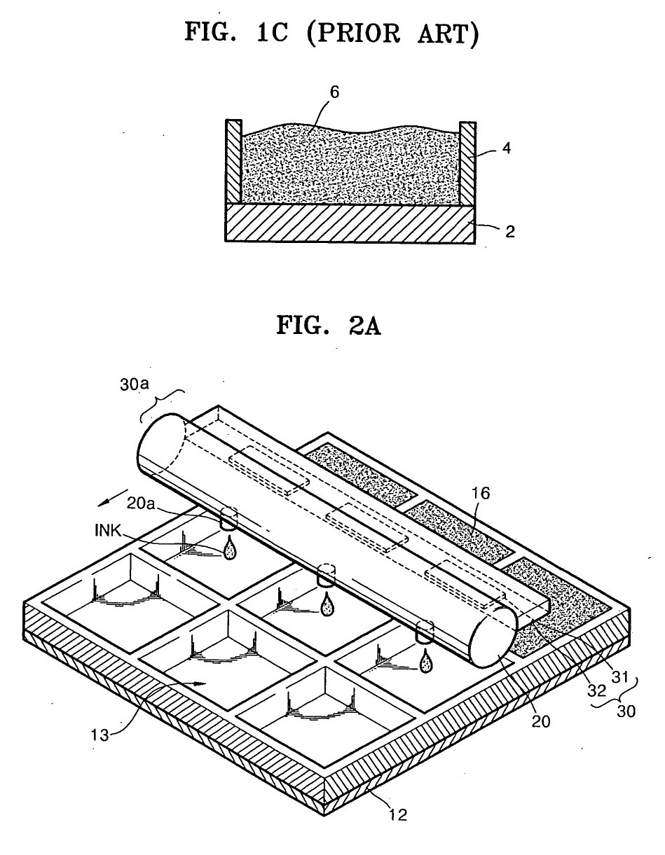

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

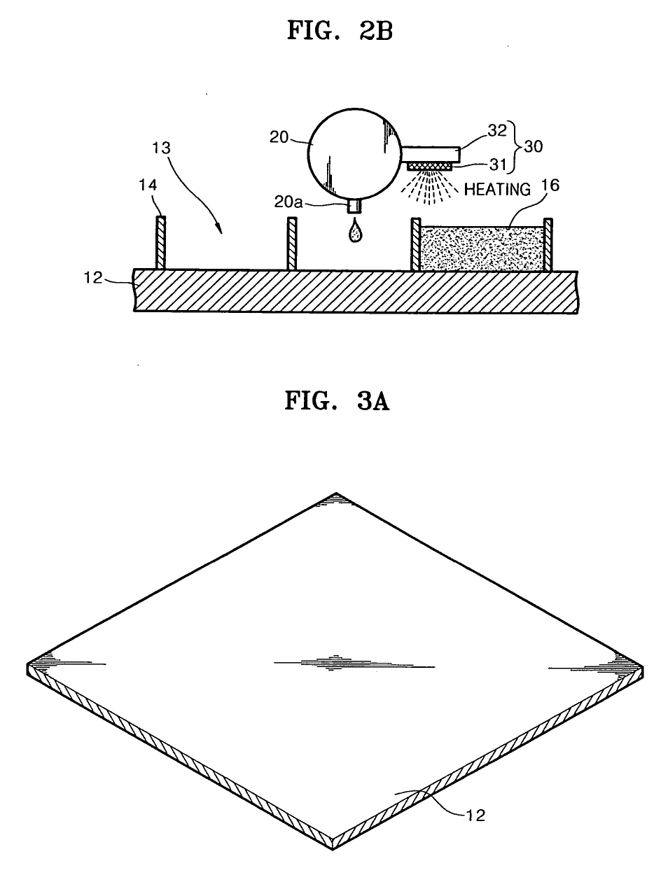

FIGS. 2A and 2B are, respectively, perspective and side views of an inkjet printhead to fabricate a color filter, according to an embodiment of the present inventive concept.

Referring to FIGS. 2A and 2B, the inkjet printhead includes an ink ejection head 20 which can eject ink 16 into a pixel 13 formed on a substrate 12 in order to fabricate the color filter, and a dryer 30 which can promptly dry the ink 16 ejected into the pixel 13. A block matrix 14 may be formed on the substrate 12 to form a number of pixels 13. The block matrix 14 and the substrate may be formed in a single body. The ink ejection head 20 may include one or more ejection nozzles 20a. When the ink ejection head 20 moves to fill the pixel 13 with the ink 16, the dryer 30 dries the ink filled in the pixel 13.

The dryer 30 includes a heating element 31 and a support head 32 supporting the heating element 31. The heating element 31 may, for example, be a micro heater or an infra red (IR) lamp. The dryer 30 may be installed at one side of the ink ejection head 20 and/or may be installed spaced apart from one side of the ink ejection head 20 by a predetermined distance. The dryer 30 may be installed in a body 30a which may be attached either with or separately from one side of the ink ejection head 20. When the dryer 30 is spaced apart from the ink ejection head 20 by the predetermined distance, the predetermined distance may be a distance less than or equal to a length of the pixel 13 in a moving direction of the ink ejection head 20. It is also possible that the predetermined distance is a distance less than a length of the color filter in the moving direction of the ink ejection head 20.

In a case where a color filter is formed using the above inkjet printhead, while the ink 16 is being ejected from an ejection nozzle 20a of the ink ejection head 20 into the pixel 13, the dryer 30 may be automatically operated to promptly dry the ejected ink 16. That is, the ink 16 filled in the pixels 13 is not dried by a natural process such as air drying, but dried by the dryer 30. “Promptly dry the ejected ink 16” refers to a drying operation in which the ink is dried during being ejected into pixel 13, or just after the pixel is completely filled with the ink 16, or before the ink ejection head 20 finishes filling pixel 13 located on a last row of the color filter. The dryer 30 may be installed at a side opposite a moving direction of the ink ejection head 20, and/or may move with and be attached to the ink ejection head 20 to form the body 30a so that the ink 16 ejected from the ink ejection head 20 can be promptly dried.

The inkjet printhead may be provided with a predetermined number of micro heaters or infra red (IR) lamps as may be necessary in order to correspond to a number of ejection nozzles 20a. In this case, each of the micro heaters or IR lamps 31 may have the same or similar width as the pixel 13.

The ink 16 may include a solvent, a pigment, a dispersant, and/or a binder. The inkjet printhead can equalize a vaporizing speed of the solvent in the respective pixels 13 by promptly drying the ink 16 ejected into the respective pixels 13. Accordingly, pigment aggregation due to differences between solvent vaporizing characteristics of the respective pixels 13 may be minimized, and the color filter may be formed in a uniform thickness.

Therefore, a color spot between an edge region pixel and a center region pixel can be suppressed to enhance color characteristics of the color filter. In addition, since the ink ejected into the pixel can be automatically dried within a short period of time, the color filter can be rapidly fabricated, thereby enhancing a production rate of color filters.

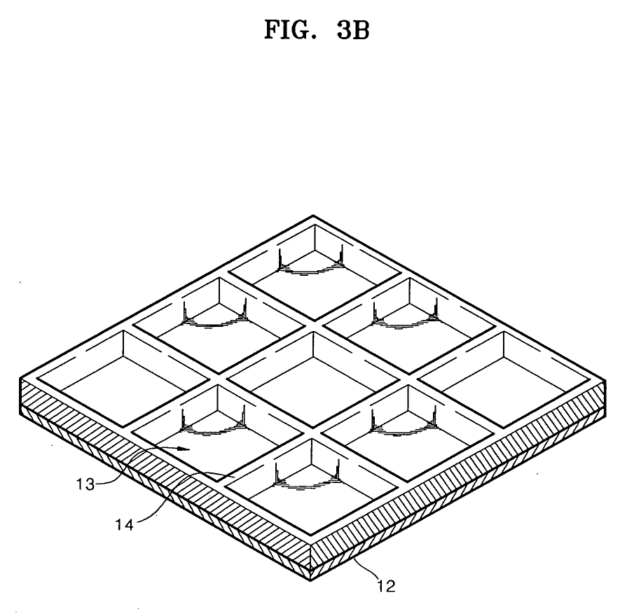

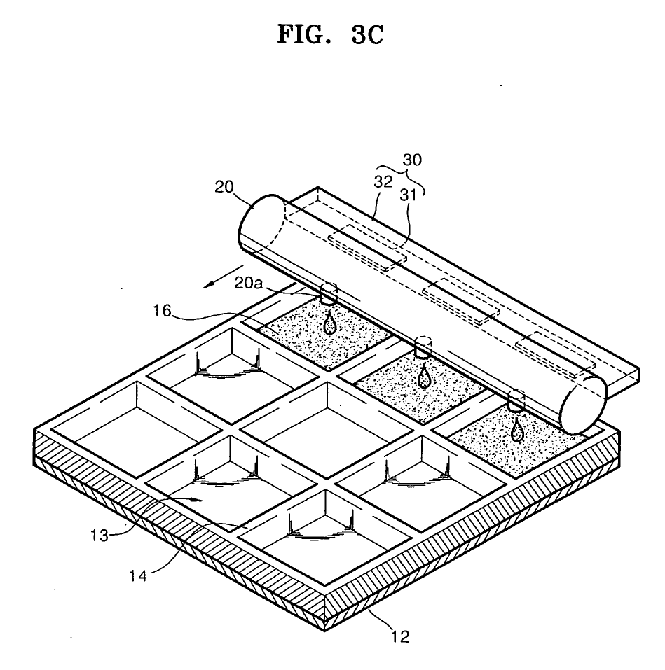

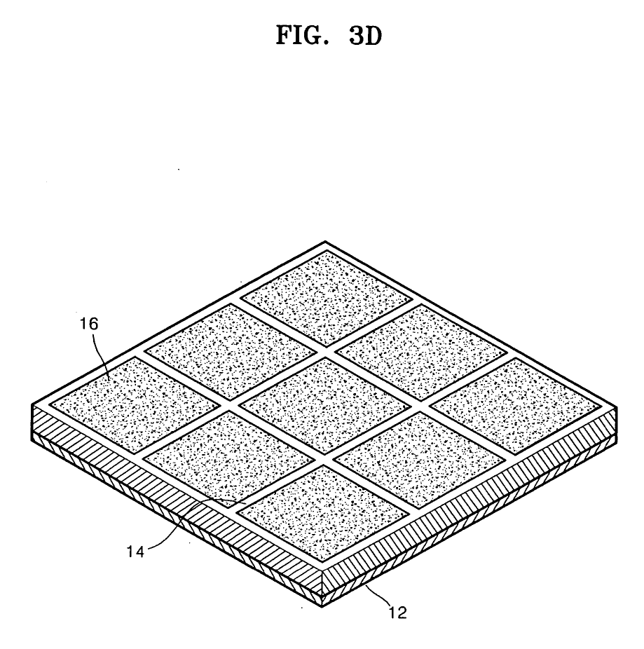

FIGS. 3A and 3D are perspective views illustrating a color filter fabrication method of fabricating a color filter using an ink ejection head according to an embodiment of the present inventive concept. Like reference numerals in FIGS. 2A, 2B, and 3A through 3D denote like elements, and thus their description will be omitted.

Referring to FIGS. 3A and 3B, a transparent substrate 12 may first be prepared, and then a block matrix 14 corresponding to a pattern of pixels 13 may be formed on the transparent substrate 12. This process may be performed by general photolithography.

Referring to FIGS. 3C and 3D, at least one pixel 13 of the transparent substrate 12 may be selected, and an ink 16 for fabricating a color filter is ejected into the selected pixel 13. Thereafter, the ejected ink 16 is promptly dried using a dryer 30. The dryer 30 includes a heating element 31 and a support head to support the heating element 31. The heating element 31 can heat and dry the ejected ink 16. The heating element 31 may be a micro heater or an IR lamp. The ink ejection head 20 moves along an arrow direction to eject the ink 16 into a plurality of pixels 13 line by line or row by row disposed in a direction having an angle with the arrow direction. The angle direction may be substantially 90 degrees.

The ejecting of the ink 16 into the pixel 13 may be performed simultaneously with the drying of the ejected ink 16. These two processes may be continuously repeated several times to fabricate the color filter. By the above processes, it is possible to fabricate a color filter with an improved thickness uniformity. When the ink ejection head 20 ejects the ink 16 into the pixel 13, the dryer 30 which generates heat to dry an adjacent pixel may continue to generate the heat to dry the pixel 13 which is being filled with the ink. In this case, the adjacent pixel has already been filled with the ink while the pixel 13 is being filled with the ink 16.

As described above, according to the embodiments of the general inventive concept, a color filter with an improved thickness uniformity can be fabricated by rapidly drying the ink ejected into the pixel. Accordingly, color mottle between an edge region pixel and a center region pixel can be suppressed, and thus color characteristics of the color filter can be enhanced. Also, since the ink ejected into the pixel is automatically dried within a short period of time, and a production rate of color filters can be increased.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An inkjet printhead to form a color filter, comprising:
an ink ejection head including one or more ejection nozzles to eject ink into a pixel formed on a substrate; and
a dryer installed near the ink ejection head to promptly dry the ink ejected into the pixel.

2. The inkjet printhead of claim 1, wherein the dryer is installed at one side of the ink ejection head.

3. The inkjet printhead of claim 2, wherein the dryer is installed in a body either attached with or separately from the ink ejection head.

4. The inkjet printhead of claim 1, wherein the dryer comprises a heating element and a support head to support the heating element.

5. The inkjet printhead of claim 4, wherein the heating element comprises a micro heater or an IR lamp.

6. The inkjet printhead of claim 4, wherein:
the one or more ejection nozzles comprise a predetermined number of ejection nozzles;
the heating element comprises a predetermined number of heating elements corresponding to the predetermined number of ejection nozzles; and
each of the heating elements comprises a micro heater or an IR lamp.

7. The inkjet printhead of claim 6, wherein the micro heater or the IR lamp has the same or similar width as the pixel.

8. The inkjet printhead of claim 1, wherein the dryer is installed at a side opposite a moving direction of the ink ejection head.

9. The inkjet printhead of claim 1, wherein the dryer is installed spaced apart from one side of the ink ejection head by a predetermined distance.

10. A method of fabricating a color filter, the method comprising:
preparing a transparent substrate;
forming a block matrix of a pixel pattern on the transparent substrate;
selecting at least one pixel of the pixel pattern on the transparent substrate and ejecting an ink into the selected pixel to fabricate a color filter; and
promptly drying the ejected ink using a dryer.

11. The method of claim 10, wherein the dryer comprises a heating element and a support head to support the heating element.

12. The method of claim 11, wherein the heating element comprises a micro heater or an IR lamp.

13. The method of claim 10, wherein the ejecting of the ink into the pixel is performed simultaneously with the drying of the ejected ink.

14. The method of claim 10, wherein the ejecting of the ink into the pixel and the drying of the ejected ink are continuously repeated several times.

15. The method of claim 10, wherein the forming of block matrix comprises forming the block matrix using photolithography.

16. A method of fabricating a color filter, the method comprising:
ejecting ink into a pixel formed on a substrate using an ink ejection head including one or more ejection nozzles; and
promptly drying the ink ejected into the pixel using a dryer installed near the ink ejection head.

17. A method of fabricating a color filter, the method comprising:
forming a pixel pattern including pixels on a transparent substrate;
depositing a predetermined material including a colorant in the pixels of the pixel pattern to fabricate a color filter; and
promptly drying the deposited predetermined material using a dryer.

18. The method of claim 17, wherein the pixels of the pixel pattern include at least one edge region pixel and at least one center region pixel and a thickness of the color filter is uniform as between a thickness of the at least one edge region pixel and the at least one center region pixel.

19. The method of claim 17, wherein the predetermined material is ink and the ink is deposited using an ink ejection head.

20. The method of claim 19, wherein the deposited ink further includes a solvent which has a vaporizing speed, the vaporizing speed of the solvent in the pixels being equalized by the prompt drying.

21. The method of claim 17, wherein the predetermined material is deposited simultaneously with the drying of the predetermined material and the pixels in the pixel pattern have a uniform thickness.

22. A color filter comprising:
a substrate;
a matrix on the substrate to form pixels in a pixel pattern; and ink deposited in the pixels having a uniform thickness.

23. The color filter of claim 22, wherein:
the pixels comprise at least one edge region pixel and at least one center region pixel; and
a color mottle between the at least one edge region pixel and the at least one center region pixel is suppressed.
